(19) United States
(12) Patent Application Publication
(10) Pub. No.: US 2025/0357372 A1
(43) Pub. Date: Nov. 20, 2025

(54) IC Structure with Stress-Release Pattern to Enhance Package Yield

(71) Applicant: Taiwan Semiconductor Manufacturing Company, Ltd., Hsin-Chu (TW)

(72) Inventors: Wen-Ling CHANG, Miaoli County (TW); Wen-Chiung TU, New Taipei City (TW); Chen-Chiu HUANG, Taichung City (TW); Hsiu-Wen HSUEH, Taichung City (TW); Hsiang-Ku SHEN, Hsinchu City (TW); Dian-Hau CHEN, Hsinchu (TW); Po-Hsiang HUANG, Taipei City (TW); Ke-Rong HU, Taoyuan City (TW); Cheng-Nan LIN, Hsinchu City (TW)

(21) Appl. No.: 19/283,383

(22) Filed: Jul. 29, 2025

Related U.S. Application Data
(63) Continuation of application No. 18/444,268, filed on Feb. 16, 2024.
(60) Provisional application No. 63/589,148, filed on Oct. 10, 2023.

(51) Int. Cl. H01L 23/00; H01L 23/053; H01L 23/29; H01L 25/065

(52) U.S. Cl. CPC H01L 23/562; H01L 23/053; H01L 23/293; H01L 24/16; H01L 24/32; H01L 24/73; H01L 25/0655; H01L 2224/16225; H01L 2224/32225; H01L 2224/73204

(57) ABSTRACT

The present disclosure provides an integrated circuit (IC) structure that includes a substrate having a circuit region and a chip corner region; IC devices formed on the substrate within the circuit region; a passivation layer formed over the IC devices; and a polyimide layer formed over the passivation layer, wherein the passivation layer and the polyimide layer include a stress-release pattern formed in the chip corner region.

### PRIORITY DATA

This application is a Continuation of U.S. patent application Ser. No. 18/444,268, filed Feb. 16, 2024, which further claims priority to U.S. Provisional Patent Application Ser. No. 63/589,148 filed on Oct. 10, 2023, the entire disclosures of which are hereby incorporated herein by reference.

### BACKGROUND

In semiconductor industry, integrated circuits (ICs) are formed on a semiconductor substrate and are saw to IC chips. Each IC chip is further bonded to a circuit board, such as another IC chip, a carrier substrate, an interposer or a printed circuit board in electric products. Then the integrated circuits are packaged with proper packaging materials. However, the various materials of the IC chip and the packaging components have different coefficient of thermal expansion (CTE), which may cause stress, die delamination, bump crack, circuit failure and other quality and reliability issues associated with CTE mismatch. Therefore, the present disclosure provides an IC structure and a method making the same to address the above issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a sectional view of an integrated circuit (IC) structure constructed according to various aspects of the present disclosure in some embodiments.

FIGS. 2A, 2B and 2C are sectional views of an IC structure at various fabrication stages constructed according to various aspects of the present disclosure in some embodiments.

FIG. 3 is a flowchart of a method to fabricate an IC structure in accordance with some embodiments.

FIGS. 4 and 5 are top views of an IC structure, in portion, constructed in accordance with some embodiments.

FIGS. 6A, 7A, 8A, 9A, 10A, 11A, 12A, 13A and 14A top views of an IC structure during various fabrication stages, constructed in accordance with some embodiments.

FIGS. 6B, 7B, 8B, 9B, 10B, 11B, 12B, 13B and 14B sectional views of the IC structure of FIGS. 6A, 7A, 8A, 9A, 10A, 11A, 12A, 13A and 14A, respectively, constructed in accordance with some embodiments.

FIG. 15 is a top view of an IC structure, in portion, constructed in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. It is to be understood that the following disclosure provides many different embodiments, or examples, for implementing different features of various embodiments. Specific examples of components and arrangements are described below to simplify the present disclosure. These are, of course, merely examples and are not intended to be limiting.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

The disclosed device structure and the method making the same are related to integrated circuits (IC) structure, especially, packaging structure with designed pattern to release stress and enhance packaging yield. The disclosed device structure includes various structure features and fabrication steps to provide collective structure to reduce stress and delamination in the packaging, especially packaging structure in system-on-chip (SoC) flip-chip structures.

In the present disclosure, an IC structure is configured to add trench or hole pattern into to the packaging materials, such as polyimide or silicon nitride of the passivation layer in corner area to release corner stress, thereby enhancing SoC Flip chip (FC) package yield. Those trenches or holes are referred to as stress-release pattern. The stress-release pattern is arranged within the chip corner area (keep-out zone, KOZ). The stress-release pattern is defined on a photomask and is transferred to the packaging material through lithography process and etching.

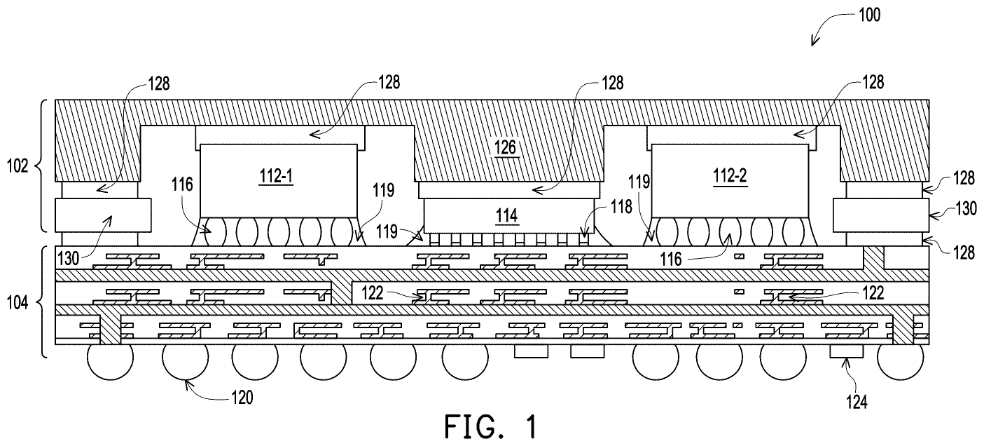

FIG. 1 is a fragmentary cross-sectional view of an IC structure 100, in portion or entirety, constructed in accordance with some embodiments. The IC structure 100 includes a three-dimensional (3D) IC structure with multiple chips integrated in a same package. The IC structure 100 includes various IC chips, such as a system-on-chip (SoC), memory chips, other suitable chips, or a combination thereof, integrated together in a packaging. One or more chips of the IC structure includes a passivation structure having various components, features and materials, such as a passivation structure with one or more passivation layer; bonding pads formed on the passivation layer; a redistribution layer (RDL) embedded in the RDL to redistribute the bonding pads; and a polyimide layer disposed on the passivation layer to provide proper sealing function. Furthermore, a underfilling (UF) layer is formed to fill the spacing between the chips. In some embodiments, the passivation structure includes a first passivation layer of silicon nitride and a second passivation layer of silicon nitride with a silicon oxide layer (such as undoped silica glass, USG). A polyimide is further formed on the top and is patterned to have openings for bond pads. Those different materials usually have different coefficients of thermal expansions (CTE), which may introduce stresses and cause delamination issues and fail the IC structure. In the disclosed structure, the passivation layer, such as the second passivation layer of silicon nitride is patterned in the chip corner areas to have various trenches, holes or combinations thereof to release stress and eliminate the delamination. The polyimide layer may further be patterned in the chip corner areas to have various trenches, holes or combinations thereof to release stress and eliminate the delamination. A chip corner area is an area in a chip corner free of integrated circuit and is also referred to as a keep out zone (KOZ), which will be further described later.

Referring to FIG. 1, the IC structure 100 is provided by arranging a chipset using a combination of multichip packaging technologies, such as chip-on-wafer-on-substrate (CoWoS) packaging technology, system-on-integrated-chips (SoIC) multi-chip packaging technology, an integrated-fan-out (InFO) package, according to various aspects of the present disclosure. The IC structure 100, which can be referred to as a 3D IC package and/or a 3D IC module, includes a CoW structure 102 attached to a substrate 104 (e.g., a package substrate). CoW structure 102 includes a chipset (e.g., a memory chip 112-1, a memory chip 112-2, a system-on-chip (SOC) 114 electrically connected to and integrated with each other) attached to the substrate 104. In some embodiments, the chipset is arranged into one or more chip stack where one chip is stacked on another chip. In the depicted embodiment, chips are directly bonded face-to-face and/or face-to-back to provide SoIC packages of multichip package. In some embodiments, a chip stack of multichip package includes a combination of chip types, such as a core chip having one or more memory chips disposed thereover. FIG. 1 has been simplified for the sake of clarity to better understand the inventive concepts of the present disclosure. Additional features can be added in multichip package, and some of the features described below can be replaced, modified, or eliminated in other embodiments of multichip package.

Memory chip 112-1 and memory chip 112-2 are high bandwidth memory (HBM) chips, GDDR memory chips, dynamic random-access memory (DRAM) chips, static random-access memory (SRAM) chips, magneto-resistive random-access memory (MRAM) chips, resistive random-access memory (RRAM) chips, other suitable memory chips, or combinations thereof. In some embodiments, memory chip 112-1 and memory chip 112-2 are HBM chips that form at least a portion of the memory device. In some embodiments, memory chip 112-1 and memory chip 112-2 are a graphics double-data rate (GDDR) memory chips that form at least a portion of the memory device. In some embodiments, memory chip 112-1 is an HBM chip and memory chip 112-2 is a GDDR memory chip, or vice versa, that form at least a portion of the memory device. In some embodiments, memory chip 112-1 and/or memory chip 112-2 represent a stack of memory dies, which can be bonded and/or encapsulated in a manner that provides a memory package and/or a memory-based SoIC package. The memory package may be an HBM package (also referred to as an HBM cube) or a GDDR memory package.

The SOC 104 is an integrated circuit chip that integrates all or a subset of the components of a computer or other electronic system. These components may include a central processing unit (CPU), memory interfaces, on-chip input/output devices, input/output interfaces, and secondary storage interfaces, radio modems, a graphics processing unit (GPU) or a combination thereof, on a single substrate. The SOC may contain digital, analog, mixed-signal, radio frequency signal processing functions or a combination thereof.

SOC chip 114, memory chip 112-1, and memory chip 112-2 are attached and/or interconnected to substrate 104. In some embodiments, the substrate 104 is an interposer. In furtherance of the embodiment, the interposer is attached and/or interconnected to an underlying substrate, such as a semiconductor substrate, a printed circuit board, or other suitable substrate. Various bonding mechanisms can be implemented in multichip package, such as electrically conductive bumps 116 (e.g., metal bumps), through semiconductor vias (TSVs), bonding pads 118, or combinations thereof. For example, electrically conductive bumps 116 physically and/or electrically connect memory chip 112-1, and memory chip 112-2 to the substrate 104. In another example, the bonding pads 118 physically and/or electrically connect the SOC chip 114 to the substrate 104. In some embodiments, electrically conductive bumps 116 that connect chips and/or chip stacks may be micro-bumps, controlled collapse chip connections (referred to as C4 bonds) (e.g., solder bumps and/or solder balls), other proper connection mechanism or a combination thereof.

An underfill material (or simply referred as by under fill or UF) 119 is further filled in the spacing between the chips and the substrate with proper sealing effect and mechanical strength. For example, the UF 119 is dispensed onto the substrate 104 and is drawn into the spacing by capillary force. The UF 119 may include one or more suitable underfill material, such as a curable polymeric material. An additional amount of the underfill material may be applied along the edges of the chip, thereby forming a uniform fillet that extends beyond the edge of the chip. The curable polymeric material is thereafter cured by a suitable method such as heating or ultraviolet (UV) energy, thereby forming the underfill. The underfill bonds the chips, the supporting substrate 104, and the solder bumps, thereby strengthening the assembly and protecting the solder bump interconnections from environmental damage. In some embodiments, the underfill material includes one or more polymerizable monomers, polyurethane prepolymers, constituents of block copolymers, constituents of radial copolymers, initiators, catalysts, cross-linking agents, stabilizers, or a combination thereof.

In some embodiments, substrate 104 is a package substrate, such as coreless substrate or a substrate with a core, that may be physically and/or electrically connected to another component by electrical connectors 120. Electrical connectors 120 are electrically connected to electrically conductive bumps 116 and bonding pads 118 through electrically conductive routing structures (paths) 122 of substrate 104. In some embodiments, substrate 104 is an interposer. In some embodiments, substrate 104 is a printed circuit board (PCB).

In some embodiments, the substrate 104 is a semiconductor substrate, such as a silicon substrate (which may generally be referred to as a silicon interposer). In some embodiments, the substrate 104 is a laminate substrate, a cored package substrate, a coreless package substrate, or the like. In some embodiments, the substrate 104 can include an organic dielectric material, such as a polymer, which may include polyimide, polybenzoxazole (PBO), benzocyclobutene (BCB), other suitable polymer-based material, or combinations thereof. In some embodiments, redistribution lines (layers) (RDLs) can be formed in the substrate 104, such as within the organic dielectric material(s) of substrate 104. RDLs may form a portion of electrically conductive routing structures 122 of the substrate 104. In some embodiments, RDLs electrically connect bond pads on one side of the substrate 104 (e.g., top side of the substrate 104 having chipset attached thereto) to bond pads on another side of the substrate 104 (e.g., bottom side of the substrate 104). In some embodiments, RDLs electrically connect bond pads on the top side of the substrate 104, which may electrically connect chips of the chipset. In some embodiments, the substrate 104 may be a semiconductor substrate having TSVs formed therein to provide electrical connection from the frontside to the backside. The IC structure 100 may further include various active devices, passive devices or combinations thereof formed on the substrate 104. For examples, the IC structure 100 includes one or more large-scale-integrated passive devices (LS-IPDs) 124 formed on the substrate 104 and electrically connected and integrated with other devices of the IC structure 100.

The IC structure 100 also include other features, components, and material configured to form a packaging structure with various functions, such as thermal dissipation, sealing mechanism, mechanical strength, and/or a combination thereof. Particularly, the IC structure 100 includes a lid 126 disposed over chips (e.g., 112-1, 112-2 and 114). The lid 126 is a structure of a thermal conductive material with heat dissipation function and is integrated with the substrate 104 to enclose the chips inside. For example, the lid 126 is designed with a lower surface being conformal with the geometrical profile of the chips integrated on the substrate 104 and with a flat top surface. In some embodiments, the lid 126 includes a material of a high thermal conductivity, such as a thermal conductive material with a thermal conductivity ranging between 200 W/m·K and 400 W/m·K. In some embodiments, the lid 126 is made of a metal, a metal alloy, grapheme, carbon nanotubes (CNT), other suitable material or a combination thereof. In some embodiments, the lid 126 is made of aluminum, steel, copper, or an alloy of these metals.

The Lid 126 is secured on the substrate 104 through a proper mechanism, such as through one or more thermal interface material (TIM) feature 128. In some embodiments, the TIM feature 128 includes a polymer having a good thermal conductivity with a thermal conductivity ranging between 2 W/m·K and 10 W/m·K. In some embodiments, the TIM feature 128 has a thickness ranging between 50 μm and 100 μm. In some embodiments, the TIM may be applied to the surface of the lid 126 and/or the surfaces of the substrate 104, and is cured by a suitable method, such as ultraviolet (UV), heating, other suitable technologies, or a combination thereof.

The lid 126 is designed with proper shape to be attached to the chips and further secure the chips to the substrate 104. In some embodiments, the lid 126 is attached to the chips through the TIM feature 128, other suitable material or a combination thereof through the similar process. For example, the TIM is applied to the surface of the lid 126 and/or the surfaces of the chips, and is cured by a suitable method, such as UV, heating, other suitable technologies, or a combination thereof. When the lid 126 is secured on the substrate 104 and enclose the chips inside, empty spaces may be formed inside the enclosure, such as between the chips. These may further provide buffer room to reduce and release the stress.

In some embodiments, the IC structure 100 may include other features, such as one or more fixtures 130 inserted between the substrate 104 and the lid 126. The fixtures 130 are designed to accommodate the lid 126 with and provide more freedom to release the stress built between the substrate 104 and the lid 126. In some embodiments, the fixtures 130 may use the material same or similar to that of the lid 126, such as a metal, a metal alloy, grapheme, CNT, other suitable material or a combination thereof.

In some embodiments, multichip package can be configured as a 2.5D IC package and/or a 2.5D IC module by rearranging the chipset, such that the substrate 104 is an interposer and each chip is bonded and/or attached to the interposer. In other words, the 2.5D IC module does not include a chip stack, and chips of the chipset are arranged in a single plane. In some embodiments, multichip package is configured as a 3D IC package and/or a 3D IC module by rearranging chips to form one or more chipset. In some embodiments, the substrate 104 is a semiconductor substrate having various devices formed thereon and the chips bonded thereon. Furthermore, the substrate 104 includes an interconnect structure formed on the frontside of the substrate and may further include an interconnect structure formed on the backside of the substrate and TSVs formed in the substrate to electrically couple the frontside interconnect structure and the backside interconnect structure.

The IC structure 100 may further include other devices, components, function units integrated such as high-density capacitors (HDPs), optical ring resonators (ORRs), inductors, imaging sensors, waveguides, other proper devices or a combination thereof, distributed on the substrate 104 and various chips (e.g., 112-1, 112-2 and 114). The IC structure 100 may additionally or alternatively include other chips integrated in the same packaging.

Particularly, various chips of the IC structure 100 are integrated with a suitable packaging structure to reduce and release stress, therefore eliminating delamination and other failure issues. Taking the SOC 114 as an example, the chip 114 is formed with various trenches and open holes formed in the chip corner regions, which will be further described below. Note that all chips (such as chips 112-1, 112-2 and 114) or at least a subset of the chips have a similar structure to reduce stress.

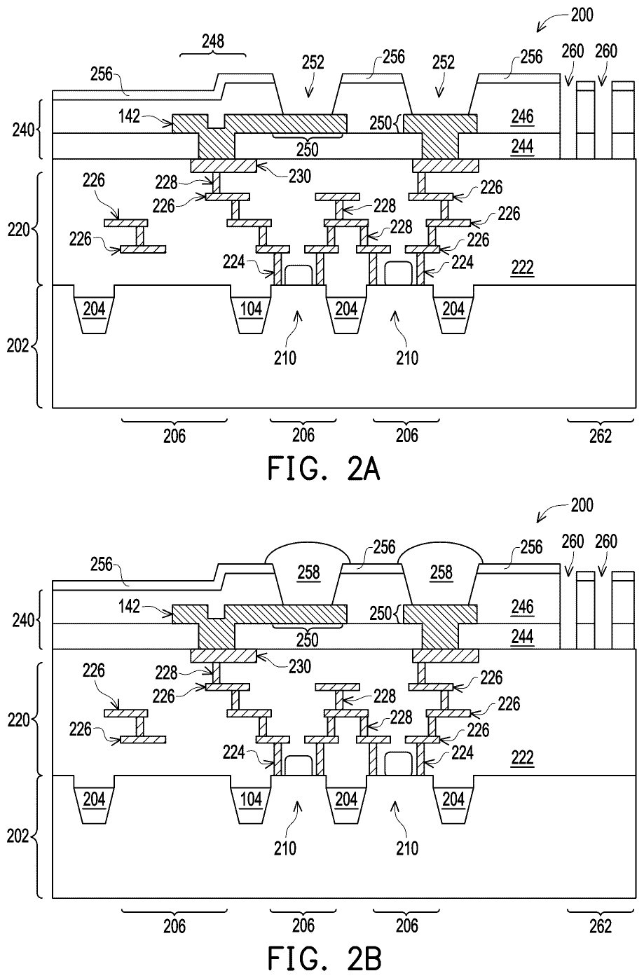

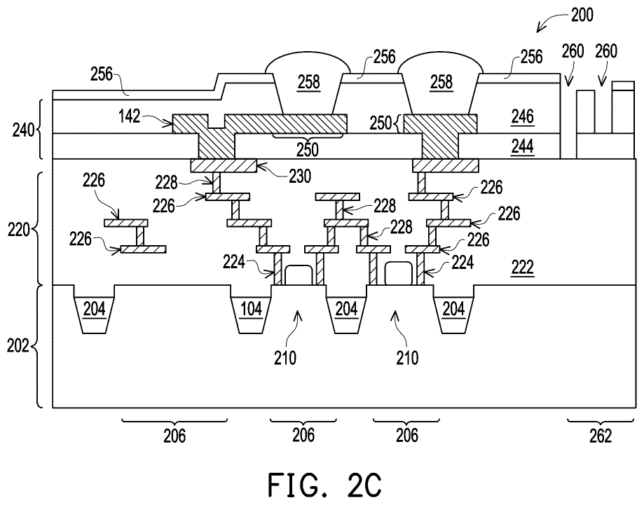

FIGS. 2A and 2B are sectional views of an IC structure 200 at various fabrication stages, in portion or entirety, constructed according to various aspects of the present disclosure in one embodiment. FIG. 3 is a flowchart of a method 300 making the IC structure 200 in accordance with some embodiments. The IC structure 200 and the method 300 making the same are collectively described with reference to FIGS. 2A, 2B, 3 and other figures. In some embodiments, the IC structure 200 is a semiconductor chip, such as the SOC chip 114, or the memory chip 112-1 or 112-2.

The IC structure 200 may include flat active regions with various IC devices, such as plain field-effect transistors (FETs), formed thereon, fin active regions with various transistors formed thereon, or multiple channels vertically stacked with various transistors formed thereon, such as gate-all-around (GAA) FETs.

The IC structure 200 includes a substrate 202. The substrate 202 includes a bulk silicon substrate. Alternatively, the substrate 202 may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrates 102 also include a silicon-on-insulator (SOI) substrate. SOI substrates are fabricated using separation by implantation of oxygen (SIMOX), wafer bonding, and/or other suitable methods.

The substrate 202 also includes various isolation features, such as isolation features 204 formed on the substrate 202 and defining various active regions on the substrate 202, such as an active region 206. The isolation feature 204 utilizes isolation technology, such as shallow trench isolation (STI), to define and electrically isolate the various active regions. The isolation feature 204 includes silicon oxide, silicon nitride, silicon oxynitride, other suitable dielectric materials, or combinations thereof. The isolation feature 204 is formed by any suitable process. As one example, forming STI features includes a lithography process to expose a portion of the substrate, etching a trench in the exposed portion of the substrate (for example, by using a dry etching and/or wet etching), filling the trench (for example, by using a chemical vapor deposition process) with one or more dielectric materials, and planarizing the substrate and removing excessive portions of the dielectric material(s) by a polishing process, such as a chemical mechanical polishing (CMP) process. In some examples, the filled trench may have a multi-layer structure, such as a thermal oxide liner layer and filling layer(s) of silicon nitride or silicon oxide.

The active region 206 is a region with semiconductor surface wherein various doped features are formed and configured to one or more device, such as a diode, a transistor, and/or other suitable devices. The active region may include a semiconductor material similar to that (such as silicon) of the bulk semiconductor material of the substrate 202 or different semiconductor material, such as silicon germanium (SiGe), silicon carbide (SiC), or multiple semiconductor material layers (such as alternative silicon and silicon germanium layers) formed on the substrate 202 by epitaxial growth, for performance enhancement, such as strain effect to increase carrier mobility.

In some embodiments, the active region 206 is three-dimensional, such as a fin active region extended above the isolation feature 204. The fin active region is extruded from the substrate 202 and has a three-dimensional profile for more effective coupling between the channel region (or simply referred to as channel) and the gate electrode of a FET. The active region 206 may be formed by selective etching to recess the isolation features 204, or selective epitaxial growth to grow active regions with a semiconductor same or different from that of the substrate 202, or a combination thereof.

The semiconductor substrate 202 further includes various doped features, such as n-type doped wells, p-type doped wells, source and drain, other doped features, or a combination thereof configured to form various devices or components of the devices. The IC structure 200 includes various IC devices 210 formed on the semiconductor substrate 202. The IC devices includes fin field-effect transistors (FinFETs), diodes, bipolar transistors, imaging sensors, resistors, capacitors, inductors, memory cells, or a combination thereof. In FIG. 2, only FETs are provided for illustration.

The IC structure 200 further includes an interconnection structure 220 formed on the semiconductor substrate 202. The interconnection structure 220 includes various conductive features to couple various IC devices into an integrated circuit. The interconnection structure 220 further includes an interlayer dielectric (ILD) layer 222 to separate and isolate various conductive features. For examples, the interconnection structure 220 includes contacts 224; metal lines 226; and vias 228. The metal lines 226 are distributed in multiple metal layers. In FIG. 2, four metal layers are illustrated. The top metal lines are separately labeled with numeral 230. The contacts 224 provide vertical electrical routing from the semiconductor substrate 202 to the metal lines. The vias 228 provide vertical electrical routing between adjacent metal layers. Various conductive features are formed by one or more conductive material, such as metal, metal alloy, or silicide. For examples, the metal lines 226 may include copper, aluminum copper alloy, other suitable conductive material, or a combination thereof. The vias 228 may include copper, aluminum copper alloy, other suitable conductive material, or a combination thereof. The contacts 224 may include tungsten, silicide, nickel, cobalt, copper, other suitable conductive material, or a combination thereof. In some examples, various conductive features may further include a barrier layer, such as tantalum and tantalum nitride, titanium and titanium nitride. In the present embodiment, the top metal lines 230 include copper.

The ILD layer 222 includes one or more dielectric material to provide isolation functions to various device components (such as gates) and various conductive features (such as metal lines, contacts and vias). The ILD layer 222 includes a dielectric material, such as silicon oxide, a low-k dielectric material, other suitable dielectric material, or a combination thereof. In some examples, the low-k dielectric material includes fluorinated silica glass (FSG), carbon doped silicon oxide, Xerogel, Aerogel, amorphous fluorinated carbon, Parylene, BCB (bis-benzocyclobutenes), polyimide, and/or other suitable dielectric materials with dielectric constant substantially less than that of the thermal silicon oxide. The formation of the ILD layer 222 includes deposition and CMP, for examples. The deposition may include spin-on coating, CVD, other suitable deposition technology or a combination thereof. The ILD layer 222 may include multiple layers and is collectively formed with various conductive features in a proper procedure, such as damascene process.

In some embodiments, the interconnection structure 220 or a portion thereof is formed by deposition and patterning. For examples, a metal (or metal alloy), such as aluminum copper is deposited by physical vapor deposition (PVD), then is patterned by lithography process and etching. Then an ILD layer is disposed on by deposition (and CMP). In some embodiments, the interconnect structure 220 uses a damascene process to form metal lines. In a damascene process, an ILD layer is deposited, may be further planarized by CMP, and then is patterned by lithography and etching to form trenches. One or more conductive material is deposited to fill the trenches, and another CMP process is applied to remove the excessive conductive material and planarize the top surface, thereby forming conductive features. The damascene process may be used to form metal lines, vias, and contacts. A dual damascene process may be applied to form one layer of metal lines and vias adjacent the metal lines. In this case, the ILD layer is deposited and patterned twice to form trenches and via holes, respectively. Then the metal is deposited to fill both the trenches and via holes to form metal lines and vias.

The IC structure 200 further includes a passivation structure 240 disposed on the interconnection structure 220 and having redistribution layer (RDL) to redistribute bonding pads, such as from the edge to the center of an IC chip for flip chip bonding or other suitable packaging technology to integrate an IC chip to another chip (in a chipset), or to a board (e.g., a printed circuit board).

The passivation structure 240 includes passivation and RDL metallic features 242 embedded in the passivation with bonding pads 250 in the openings 252 of the passivation, wherein the opening 252 is to be formed at later fabrication stage. In the present embodiment, the passivation includes a first passivation layer 244 and a second passivation layer 246 disposed on the first passivation layer 244. The first passivation layer 244 includes a redistribution via (RV) hole aligned to a top metal line 230 so that the portion 248 of a RDL metallic feature 242 is formed in the RV hole and directly contact the top metal line 230. The portion 248 of the RDL metallic feature 242 is also referred to as RV pad 248. The RDL metallic feature 242 vertically extends from the first passivation layer 244 to the second passivation layer 246 and horizontally extends from the RV pad 148 to the bonding pad 250 for pad redistribution.

In the present embodiment, the first passivation layer 244 includes a first silicon nitride (SiN) layer and a first un-doped silica glass (USG) layer on the SiN layer; and the second passivation layer 246 includes a second USG layer and a second SiN layer disposed on the second USG layer. The RDL metallic features 242 include multiple layers. In the present embodiment, the RDL metallic features 242 include a barrier layer, a diffusion layer disposed on the barrier layer and an aluminum copper alloy layer disposed on the diffusion layer. The barrier layer may further include a tantalum film and a tantalum nitride film disposed on the tantalum film. The diffusion layer is a metal oxide. In the present embodiment, the diffusion layer includes tantalum, oxygen, aluminum, and nitrogen. The diffusion layer has a thickness ranging between 5 Angstrom and 30 Angstrom. The aluminum copper alloy layer is formed at high temperature greater than 300° C. The RDL structure 240, especially the RDL metallic features 242 are further described in the following descriptions. In some embodiments, the first USG layer has a thickness ranging between 2000 angstrom and 4000 angstrom; and the first SiN has a thickness ranging between 2000 angstrom and 6000 angstrom. In some embodiments, the second USG layer has a thickness ranging between 2000 angstrom and 4000 angstrom; and the second SiN has a thickness ranging between 2000 angstrom and 6000 angstrom.

A polyimide layer 256 is formed on the passivation layer 246. The polyimide layer 256 provides protections to the circuit, such as protection from α-particles. The polyimide layer 256 is coated on the passivation layer 246 by a suitable process, such as spin-on coating. A baking process may be implemented after the spin-on coating. Furthermore, the polyimide layer 256 is designed with desired mechanical characteristics to address the cracking issues and further with manufacturing efficiency. In the present embodiment, the polyimide layer 256, in its final form after coating and patterning, is designed with compositions to have enhanced tensile strength greater than 170 MPa, such as in a range from 170 MPa to 200 MPa; and to have Young's module greater than 4 GPa, such as in a range from 4 GPa to 6 GPa. In furtherance of the embodiment, the polyimide layer 256 includes more than 40% (volume percentage, the same below) aliphatic amide (AA) or Gamma-Butyrolactone (GBL); and more than 25% polyamic acid ester (PAE). In some examples, the polyimide layer 256 includes 50% to 60% AA and 30% to 40% PAE. In some examples, the polyimide includes 40% to 60% and 25% to 35% PAE. The polyimide layer 256 with such composition can achieve the desired mechanical strengths and desired thickness. Furthermore, the polyimide also includes photosensitive chemical such that it can be simply patterned by a lithography process without etch. In some embodiments, the process to form the polyimide layer 256 further includes pre-treatment using oxygen (O2) ashing to the passivation layer 246 (especially the silicon nitride layer of the passivation layer 246) to increase the adhesion between the polyimide layer 256 and the passivation layer 246.

The passivation layer 246 (or additionally the passivation layer 244), and the polyimide layer 256 are further patterned to form openings 252 for bonding pads and openings (or trenches) 260 in the chip corner regions 262 of the IC structure 200 for releasing and reducing the stress. The openings 260 may partially penetrate through the passivation structure, such as penetrating through the passivation layer 246 but not the passivation layer 244. The passivation layers 244, 246, and the polyimide layer 256 are patterned in any proper sequence. In some embodiments, the passivation layer is patterned first, and the polyimide layer 256 is patterned thereafter to form openings 252 and 260. In this case, the passivation layer 246 is deposited and patterned, and thereafter the polyimide layer 256 is deposited and patterned.

In some embodiments, the polyimide layer 256 is patterned first, and the passivation layer is patterned thereafter to form openings 252 and 260 with continuous sidewalls for improved condition to form bonding pads. This is because the patterned polyimide layer 256 now functions as an etch mask when patterning the passivation layer and constrains the sidewalls of the patterned passivation layer 256 are aligned with the sidewalls of the polyimide layer 256. In this case, the passivation layer 246 is deposited and the polyimide layer 256 are sequentially deposited, and thereafter the polyimide layer 256 and the passivation layer 246 are sequentially patterned. In furtherance of the present embodiments, when the passivation layer is patterned, only an etching process is applied with additionally lithography process since the patterned polyimide layer 256 functions as an etch mask.

The process to pattern the passivation layer 246 includes by a lithography process and an etching process. A patterned mask is first formed by lithography process with openings to define the regions for the openings 252 and 260. The lithography process may include photoresist coating such as by spin-coating; an exposure process with a photoresist sensitive radiation, such as ultraviolet (UV) light, deep UV (DUV) light, or extreme UV (EUV) light; and developing to form the patterned photoresist layer. The lithography process may further include other processing steps, such as post-exposure baking (PEB) after the exposure process, and hard baking after the developing process. The patterned mask may be a soft mask, such as photoresist, or alternatively hard mask with any proper composition. Then the etching process with an etchant is applied to etch the passivation layer 246 to form the openings 252 and 260 in the passivation layer 246. However, as noted above, when the polyimide layer 256 is patterned first, the lithography process may be eliminated, and the passivation layer 246 is directly etched using the patterned polyimide layer 256 as an etch mask. In some embodiments where the passivation structure includes two passivation layers, both passivation layers 244 and 246 are patterned to form the openings 260 in the chip corner regions 262, in which the openings 260 penetrate through the passivation layers 244 and 246. The etching process may be wet etch, dry etch or a combination thereof. The etching process may include multiple etch steps with respective etchants to selectively etch corresponding materials of the passivation layers, such as an etchant containing hydrofluoric acid to selectively etch silicon oxide and an etchant containing phosphorous acid to selectively etch silicon nitride.

The etching process to pattern the polyimide layer 256 may include a lithography process and an etching process. The lithography process is similar to the lithography process applied to the passivation layer. The etching process may be wet etch, dry etch or a combination thereof. For example, the polyimide layer 256 is etched by a plasma etch using a chemical gas containing oxygen, fluoride or both, such as a gas containing O2, CF4, and CF6. In some embodiments, the polyimide layer 256 is designed as photosensitive and is directly patterned by a lithography process. For example, the polyimide layer 256 includes various compositions as described above, and further includes photosensitive chemical (such as photoacid generator) and solvent (such as aqueous solvent or organic solvent) all mixed together. The polyimide layer 256 undergoes a property change when being exposed to radiation energy, such as UV, DUV, EUV light. This property change can be used to selectively remove exposed portions or alternatively unexposed portions of the polyimide layer by a developing process.

Thereafter, the conductive bumps 258 are formed on the bonding pads 250 in the openings 252. The formation of the conductive bumps 258 includes depositing various conductive materials to fill in the opening 252 using suitable deposition technique. In some embodiment, the conductive bumps 258 includes under bump metallization (UBM), a copper layer, and solder, as illustrated in FIG. 2B.

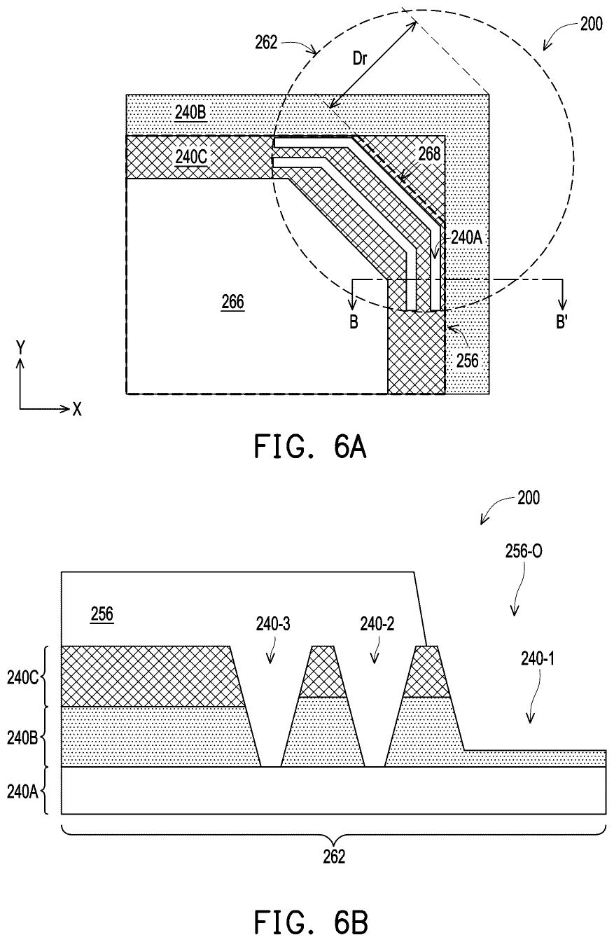

The openings 260 may have different depths, shapes, dimensions, duty ratios, configurations or a combination thereof to optimized effect of stress-releasing, such as those illustrated in FIGS. 6A through 6I. For example, the openings 260 may extend through the polyimide layer 256, the second passivation layer 246 or through the first passivation layer 244. In other examples, the openings 260 in the polyimide layer 256 and the passivation layers 244, 246 are different in location, dimension and shape, such as illustrated in FIG. 2C. FIG. 2C is a top view of the IC structure 200, in portion, constructed according to some embodiments. In FIG. 2C, the openings 260 formed in the polyimide layer 256 and the passivation layers 244, 246 are different.

FIG. 3 is a flowchart of a method 300 making the IC structure 200 in accordance with some embodiments. Some fabrication details are provided above and are not repeated here. The method 300 includes an operation 301 to receive or provide a semiconductor substrate having a circuit region and chip corner regions; an operation 302 to form isolation features 204 on the semiconductor substrate 202; an operation 304 to form various IC devices (such as FETs, diodes, passive devices, imaging sensors, memory cells, other suitable IC devices or a combination thereof) on the semiconductor substrate 202; an operation 306 to form an interconnection structure 220 (such as contacts 224, metal lines 226, vias 228 and top metal lines 230) by a suitable method, such as damascene process; and an operation 308 to form a passivation structure and the polyimide layer 256 with the openings 260 (and the openings 252). The method 300 may include other operations before, during or after the above operations. The openings 260 formed in the passivation layer 246 (and additionally passivation layer 244) and the polyimide layer 256 are further described below with a method 308 in FIG. 3.

The method 308 includes an operation 312 to form the passivation layer 246 on the semiconductor substrate 202; an operation 324 to pattern the passivation layer 246 to form the openings 260 (and the openings 252); an operation 316 to form the polyimide layer 256; and an operation 318 to pattern the polyimide layer 256 extend the openings 260 (and the openings 252). In some embodiments, the openings 252 and the openings 260 may be separately formed. The openings 260 are also referred to as a stress-release pattern. The stress release patterns formed in the passivation layer and the polyimide layer may be different, therefore are referred to as a stress-release passivation pattern and a stress-release polyimide pattern, respectively. The stress release passivation patterns and the stress release polyimide pattern can be properly adjusted through adjust respective patterns defined on the respective photomasks since the operation 324 to pattern the passivation layer 246 and an operation 318 to pattern the polyimide layer 256 are implemented by a procedure that includes a lithography process using a photomask and an etching process.

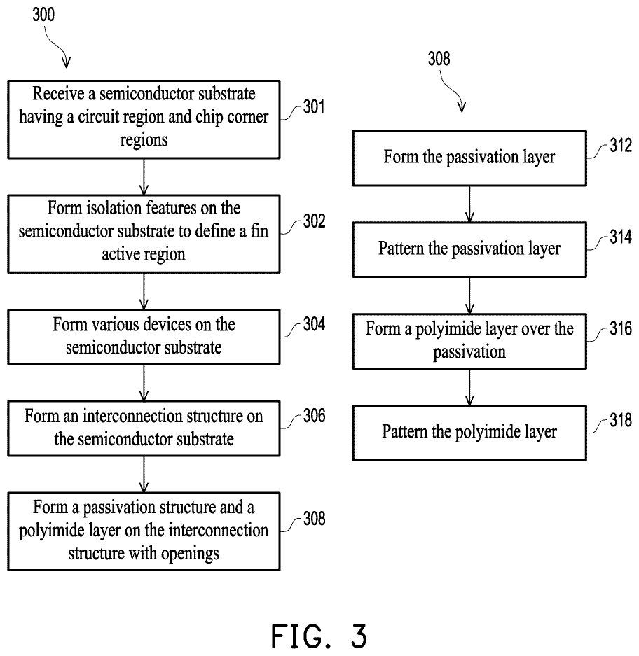

The openings 260 and the chip corner regions 262 are further described with reference to FIG. 4. FIG. 4 is a top view of the IC structure 200, in portion, constructed according to some embodiments. The chip 200 may include edges along X and Y directions, respectively. X and Y directions are perpendicular to each other. Especially, the openings 260 are illustrated. As noted above, the IC structure 200 is a chip, such as chip 114, 112-1 or 112-2. The IC structure 200 includes a circuit region 266 and chip corner regions 262. The openings 260 are designed for releasing stress and are formed on the chip corner regions 262. The chip corner regions 262 may have a dimension Dc ranging between 50 μm and 100 μm. The openings 260 may have any proper shape, such as square holes, round holes, elongated trenches, or combinations thereof.

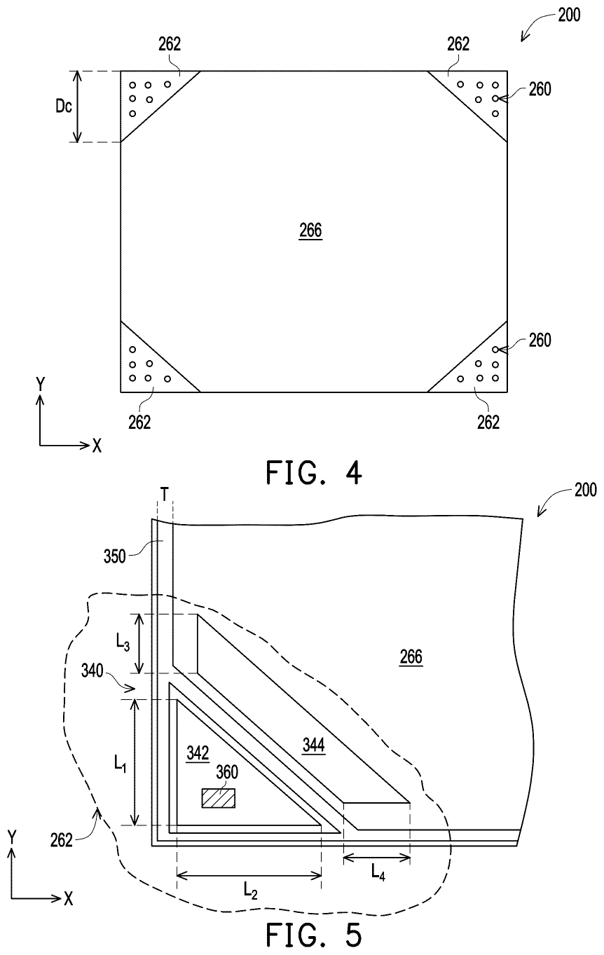

FIG. 5 is a top view of the IC structure 200, in portion, constructed according to some embodiments. The chip corner regions 262 are also referred to as a keep-out zone (KOZ) or a chip-corner-circuit-forbidden (CCCF) region. The chip corner regions 262 are located in the corners of the IC structure 200. The devices of the integrated circuit are excluded from the KOZ 262 because it is a region that may experience greater stress during and after backend processing such as die sawing and packaging. The chip corner region 262 may include a dummy metal pattern 340 for chip corner stress relief. The dummy metal pattern 340 may include a first corner stress relief (CSR) zone 342 and may further include a second CSR zone 344. The first and second CSR zones (342 and 344) may be positioned within the chip corner region 262 to be proximate to each other and configured such that the first CSR zone 342 is closest to the outline of chip corner region 262 and the second CSR zone 344 is closest to the integrated circuit region 266. An exemplary shape of the first CSR zone 342 may be designed to substantially occupy in a triangular area, preferably a right triangle, in the chip corner region 262. An exemplary shape of the second CSR zone 344 may be designed to substantially occupy in a parallelepiped area or a trapezoid area, in the chip corner region 262. An exemplary size of the first CSR zone 342 may have outlines L1 and L2 ranging from about 50 μm to about 150 μm. An exemplary size of the second CSR zone 344 may have outlines L3 and L4 ranging from about 50 μm to about 200 μm. The chip corner region 262 may further include a portion of a seal ring 350. The seal ring 350 and the dummy metal patterns 340 are formed in the same level with the interconnect structure 220 for sealing effect and releasing stress. The openings 260 are formed in the passivation structure 240 and the polyimide layer 256. In previous designs, the registration feature and chip corner region are designed separately and positioned at different location of a chip. Therefore, circuit layout and arrangement are impacted by the resultant available chip surface area and maximum chip area utilization is limited. In the structures described above, the corner stress relief pattern and registration feature are combined and co-located to maximize chip real estate available for circuit layout.

A registration feature 360 may be formed within the chip corner region 262. Such a combined structure having the registration feature 360 co-located with the first CSR zone 342, the second CSR zone 344, and/or the seal ring 350 can use chip area more efficiently and save more chip area for the integrated circuit layout. The registration feature 360 may include a laser fuse mark such as a commonly used L-shaped mark (L-mark). The laser fuse mark may implement a structure having a reverse tone composition in which the laser fuse mark comprises a first material and the surrounding region comprises a second material, which is different from the first material such that the laser fuse mark has a high contrast for registration identification. For example, the laser fuse mark may comprise a dielectric material while the surrounding region comprises a metal material. The dielectric material to form the laser fuse mark may include silicon oxide, silicon nitride, silicon oxynitride, spin-on glass (SOG), low-k material, or combinations thereof. The laser fuse mark may be disposed within the top metal layer and, alternatively, may be further extended to the substrate. The dummy metal pattern 340 in the chip corner region 262 may be fabricated simultaneously with the interconnect structure 220 in the circuit region 266 using a method such as dual damascene processing. In one embodiment the dummy metal pattern 340 may include copper, copper alloy, titanium, titanium nitride, tantalum, tantalum nitride, tungsten, polysilicon, metal silicide, or combinations thereof. The dummy metal pattern 340 may be formed using a dual damascene process.

The seal ring 350 and the dummy metal patterns 340 in the chip corner region 262 are formed in the same level with the interconnect structure 220 for sealing effect and releasing stress while the openings 260 in the chip corner region 262 are formed in the passivation structure 240 and the polyimide layer 256. The openings 260 may have different depths, shapes, dimensions, duty ratios, configurations or a combination thereof to optimized effect of stress-releasing. For example, the openings 260 may extend through the polyimide layer 256, the second passivation layer 246 or further through the first passivation layer 244. In other examples, the openings 260 in the polyimide layer 256 and the passivation layers 244, 246 are different in location, dimension, and shape, such as those illustrated in FIGS. 6A through 14B.

FIGS. 6A through 14A are top views of the IC structure 200, in portion, and FIGS. 6B through 14B are sectional views of the IC structure 200 along BB′ of FIGS. 6A through 14A, respectively, in portion, constructed according to various embodiments.

Referring to FIGS. 6A and 6B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. Especially, as noted above, the passivation layer includes a first passivation layer 244 and a second passivation layer 246 over the first passivation layer 244. The first passivation layer 244 further includes a silicon nitride layer and a USG layer, and the second passivation layer 246 further includes a USG layer and a silicon nitride layer. Collectively, the passivation structure 240 includes a first SiN layer 240A, a USG layer 240B over the first SiN layer 240A, and a second SiN layer 240C over the USG layer 240B. Various openings are formed in the polyimide layer 256 and the passivation structure 240, and are separately referred to as 256-O, 240-1, 240-2 and 240-3. In FIG. 6B and the following top view figures, the polyimide layer 256 is illustrated as transparent so that underlying features can be seen in those figures.

In the present embodiment, the polyimide layer 256 is patterned to have an opening 256-O on the edge of the chip corner region 262 while the polyimide layer 256 fill the area enclosed in the dashed line box in FIG. 6A. The polyimide layer 256 is represented by the dashed line box in FIG. 6A so that other underlying material layers of the passivation structure 240 can be visible in FIG. 6A. The opening 256-O of the polyimide layer 256 is designed such that the vertex is eliminated, and the sharp corner of the polyimide layer 256 is recessed with a tilted edge 268 not in parallel with any chip edge. The tilted edge 268 of the polyimide layer 256 is distanced from the vertex of the second passivation layer 240C with a dimension greater than 10 μm. This can effectively reduce the stress between the polyimide layer 256 and the passivation structure 240.

In the present embodiment, the passivation structure 240 is patterned to have an opening 240-1, trenches 240-2 and 240-3. The opening 240-1 of the passivation structure 240 is overlapped with the opening 256-O of the polyimide layer 256 but is different in shape, as illustrated in FIG. 6A. Especially, the opening 240-1 of the passivation structure 240 includes vertex distanced from the tilted edge 268 of the polyimide layer 256. Especially, the opening 240-1 extends to the USG layer 240B and may reduce the thickness of the USG layer 240B in edge areas, as illustrated in FIG. 6B.

In the present embodiment, the passivation structure 240 is patterned to have trenches 240-2 and 240-3 in the chip corner region 262. The trenches 240-2 and 240-3 are configured in parallel. Each of the two trenches 240-1 and 240-2 includes three segments, with one segment being in parallel with the tilted edge 268 of the polyimide layer 256, and other two segments in parallel with the respective chip edges. The three segments are connected to form a continuous trench structure. The trenches 240-2 and 240-3 of the passivation structure 240 are extending to the first SiN layer 240A so that the first SiN layer 240A is exposed with the trenches 240-2 and 240-3. In some embodiments, the two trenches 240-2 and 240-2 spans a same width. In some embodiments, the two trenches 240-2 and 240-2 are distanced with a spacing greater than the width of the trench 240-2 (or the trench 240-2).

Those openings are formed with proper dimensions for effective stress-releasing. In some embodiments, each of these openings has dimensions greater than 2 μm. For example, the trenches 240-2 and 240-2 have a dimension greater than 2 μm. Each segment of the trenches 240-2 and 240-3 has a length greater than 10 μm. In another example, the opening 240-1 has a width greater than 10 μm. In yet another example, the opening 256-O has a width greater than 10 μm.

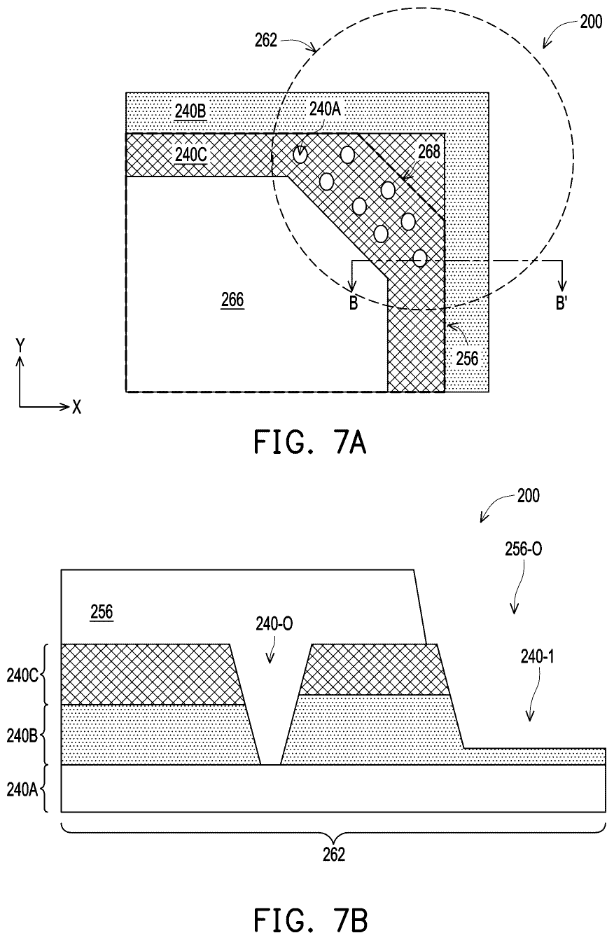

Referring to FIGS. 7A and 7B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 7A and 7B is similar to the IC structure 200 in FIGS. 6A and 6B. Similar descriptions are repeated for simplicity. Various openings 260 are formed in the polyimide layer 256 and the passivation structure 240, and are separately referred to as 256-O, 240-1, and 240-O.

In the present embodiment, the polyimide layer 256 is patterned to have an opening 256-O on the edge of the chip corner region 262 similar to the opening 256-O in FIGS. 6A and 6B. For example, the opening 256-O of the polyimide layer 256 is designed with a tilted edge 268 not in parallel with any chip edge. The tilted edge 268 of the polyimide layer 256 is distanced from the vertex of the second passivation layer 240C with a dimension greater than 10 μm.

In the present embodiment, the passivation structure 240 is patterned to have an opening 240-1, and plurality of openings 240-O. The opening 240-1 of the passivation structure 240 is similar to the opening 240-1 of the passivation structure 240 in FIGS. 6A and 6B.

In the present embodiment, instead of forming the trenches 240-2 and 240-3 of the passivation structure 240 in the chip corner region 262, a plurality of openings 240-O is formed in the passivation structure 240. Those openings 240-O of the passivation structure 240 are different from the trenches 240-2 and 240-3. Each of the openings 240-O each includes dimensions Dx and Dy along X and Y directions are substantially the same, or Dx=Dy=D. For example, the openings 240-O are round, square or combinations thereof. The openings 240-O are distributed, sized and configured in a way to effectively release the stress. In some embodiments, the dimension D of the openings 240-O are different, such as with D gradually increasing toward the tilted edge 268. In some embodiments, the openings 240-O are regularly configured in terms of size and location. For example, the openings 240-O have the same size D and regularly configured in two lines to mimic the two trenches 240-2 and 240-3 in FIGS. 6A and 6B. In furtherance of the example, the size D equals to the width W of the trenches 240-2 and 240-3. In the present embodiment, the size D is greater than 2 μm.

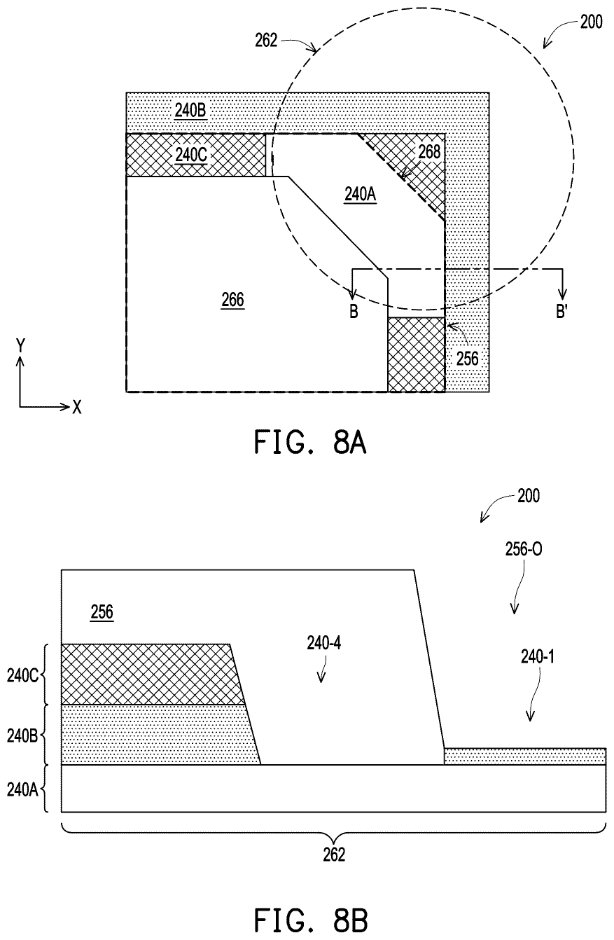

Referring to FIGS. 8A and 8B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 8A and 8B is similar to the IC structure 200 in FIGS. 6A and 6B. Similar descriptions are repeated for simplicity. Various openings 260 are formed in the polyimide layer 256 and the passivation structure 240, and are separately referred to as 256-O, 240-1, and 240-4.

In the present embodiment, the polyimide layer 256 is patterned to have an opening 256-O on the edge of the chip corner region 262 while the polyimide layer 256 fill the area enclosed in the dashed line box in FIG. 8A. The opening 256-O of the polyimide layer 256 is similar to the opening 256-O in FIGS. 6A and 6B.

In the present embodiment, the passivation structure 240 is patterned to have an opening 240-1, and trench 240-4. The opening 240-1 of the passivation structure 240 is similar to the opening 240-1 of the passivation structure 240 in FIGS. 6A and 6B.

In the present embodiment, the passivation structure 240 is patterned to have a trench 240-4, which is similar to the trenches 240-2 and 240-3 in FIGS. 6A and 6B. However, the trench 240-4 is wider than the trenches 240-2 and 240-3 in FIGS. 6A and 6B. The trench 240-4 includes three segments, with one segment being in parallel with the tilted edge 268 of the polyimide layer 256, and other two segments in parallel with the respective chip edges along X and Y directions. The three segments are connected to form a continuous trench structure. The trench 240-4 is laterally spanning between the edges (including the tilted edge 268) of the polyimide layer 256 and the edge of the circuit region 266. The trench 240-4 of the passivation structure 240 is vertically extending to the first SiN layer 240A so that the first SiN layer 240A is exposed with the trench 240-4. In some embodiments, the trench 240-4 has dimensions greater than 2 μm. For example, the trench 240-4 has a dimension from the tilted edge 268 to the edge of the circuit region 266 greater than 20 μm.

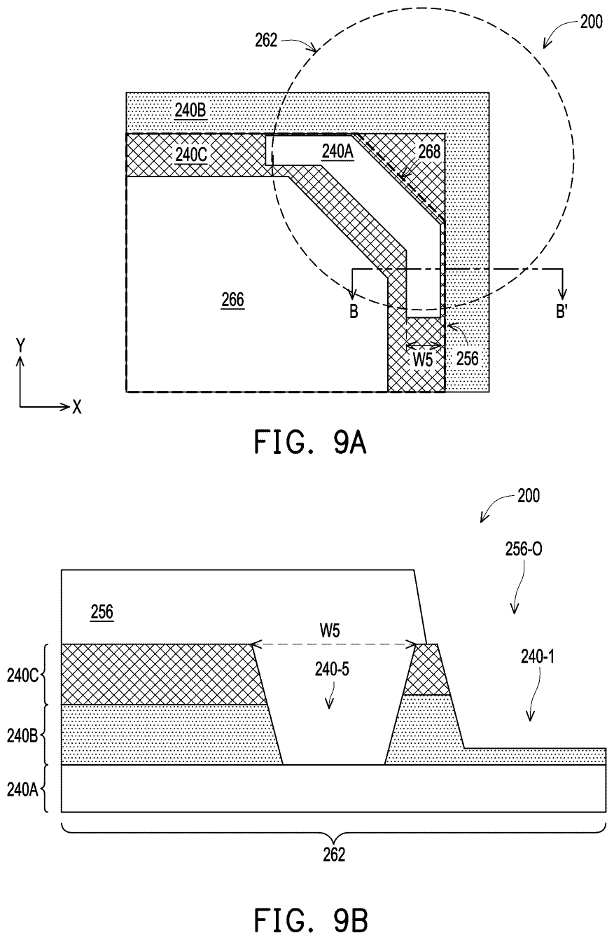

Referring to FIGS. 9A and 9B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 9A and 9B is similar to the IC structure 200 in FIGS. 8A and 8B. Similar descriptions are repeated for simplicity. Various openings 260 are formed in the polyimide layer 256 and the passivation structure 240, and are separately referred to as 256-O, 240-1, and 240-5.

In the present embodiment, the polyimide layer 256 is patterned to have an opening 256-O on the edge of the chip corner region 262 while the polyimide layer 256 fill the area enclosed in the dashed line box in FIG. 9A. The opening 256-O of the polyimide layer 256 is similar to the opening 256-O in FIGS. 6A and 6B.

In the present embodiment, the passivation structure 240 is patterned to have an opening 240-1, and trench 240-5. The opening 240-1 of the passivation structure 240 is similar to the opening 240-1 of the passivation structure 240 in FIGS. 6A and 6B.

The trench 240-5 is similar to the trench 240-4 in FIGS. 8A and 8B. The trench 240-5 includes three segments, with one segment being in parallel with the tilted edge 268 of the polyimide layer 256, and other two segments in parallel with the respective chip edges along X and Y directions. The three segments are connected to form a continuous trench structure. The trench 240-5 of the passivation structure 240 is vertically extending to the first SiN layer 240A so that the first SiN layer 240A is exposed with the trench 240-4. However, the trench 240-5 narrower than the trench 240-4 in FIGS. 8A and 8B. Specifically, the trench 240-5 is laterally extending to the edges (including the tilted edge 268) of the polyimide layer 256 but is distanced from the edge of the circuit region 266. In some embodiment, the trench 240-5 of the passivation structure 240 has a uniform width W5 greater than 10 μm. For example, the trench 240-4 has a dimension from the tilted edge 268 to the edge of the circuit region 266 greater than 20 μm.

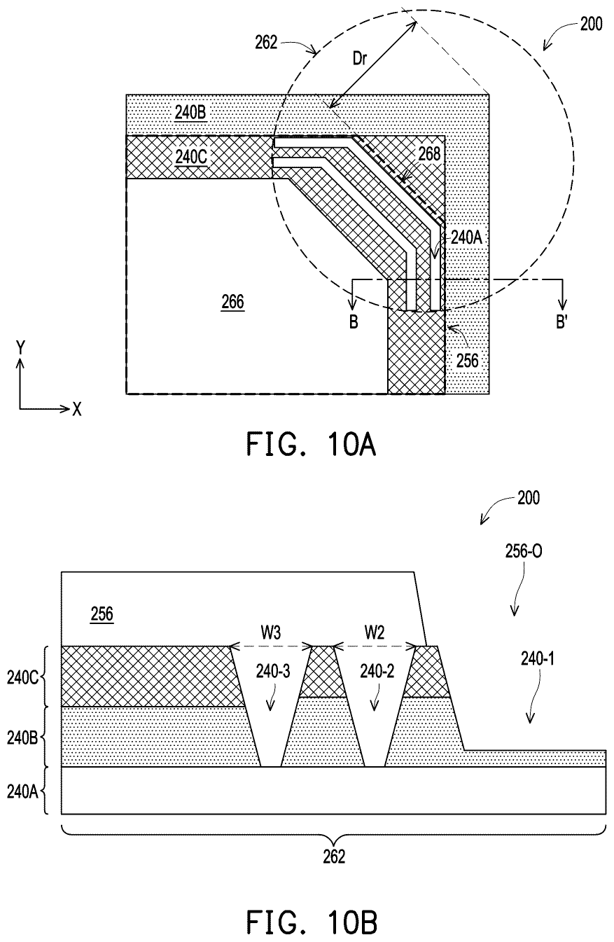

Referring to FIGS. 10A and 10B, the IC structure 200 only illustrates the passivation structure 240 and polyimide layer 256 in the chip corner region 262 and the openings formed therein and designed for reducing and releasing the stress. The IC structure 200 in FIGS. 10A and 10B is similar to the IC structure 200 in FIGS. 6A and 6B. Similar descriptions are repeated for simplicity. Various openings 260 are formed in the polyimide layer 256 and the passivation structure 240, and are separately referred to as 256-O, 240-1, 240-2 and 240-3.

In the present embodiment, the polyimide layer 256 is patterned to have an opening 256-O on the edge of the chip corner region 262 while the polyimide layer 256 fill the area enclosed in the dashed line box in FIG. 10A. The opening 256-O of the polyimide layer 256 is similar to the opening 256-O in FIGS. 6A and 6B.

In the present embodiment, the passivation structure 240 is patterned to have an opening 240-1, and trenches 240-2 and 240-3. The opening 240-1 of the passivation structure 240 is similar to the opening 240-1 of the passivation structure 240 in FIGS. 6A and 6B.

The trenches 240-2 and 240-3 are similar to the trenches 240-2 and 240-3 in FIGS. 6A and 6B but with different widths W2 and 3. specifically, W3 is greater than W2. In some embodiment, each of W2 and W3 is greater than 10 μm. In some embodiments, the ratio W3/W2 is greater than 1.2.

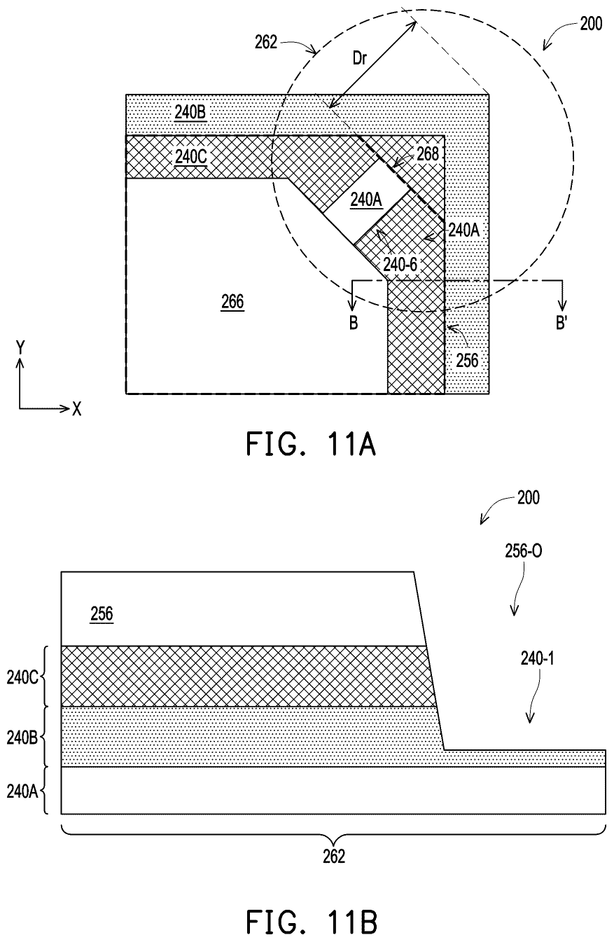

Referring to FIGS. 11A and 11B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 11A and 11B is similar to the IC structure 200 in FIGS. 8A and 8B. Similar descriptions are repeated for simplicity. Various openings 260 are formed in the polyimide layer 256 and the passivation structure 240, and are separately referred to as 256-O, 240-1, and 240-6.

In the present embodiment, the polyimide layer 256 is patterned to have an opening 256-O on the edge of the chip corner region 262 while the polyimide layer 256 fill the area enclosed in the dashed line box in FIG. 11A. The opening 256-O of the polyimide layer 256 is similar to the opening 256-O in FIGS. 6A and 6B.

In the present embodiment, the passivation structure 240 is patterned to have an opening 240-1, and a trench 240-6. The opening 240-1 of the passivation structure 240 is similar to the opening 240-1 of the passivation structure 240 in FIGS. 6A and 6B.

The trench 240-6 is similar to the trench 240-4 in FIGS. 8A and 8B. However, the trench 240-6 is only a portion of the trench 240-4 in FIGS. 8A and 8B. The trench 240-6 only includes one segment laterally spanning between the tilted edge 268 of the polyimide layer 256 and the edge of the circuit region 266. The trench 240-6 of the passivation structure 240 is vertically extending to the first SiN layer 240A so that the first SiN layer 240A is exposed with the trench 240-6. In some embodiments, the trench 240-6 has dimensions greater than 2 μm. For example, the trench 240-6 has a dimension from the tilted edge 268 to the edge of the circuit region 266 greater than 20 μm.

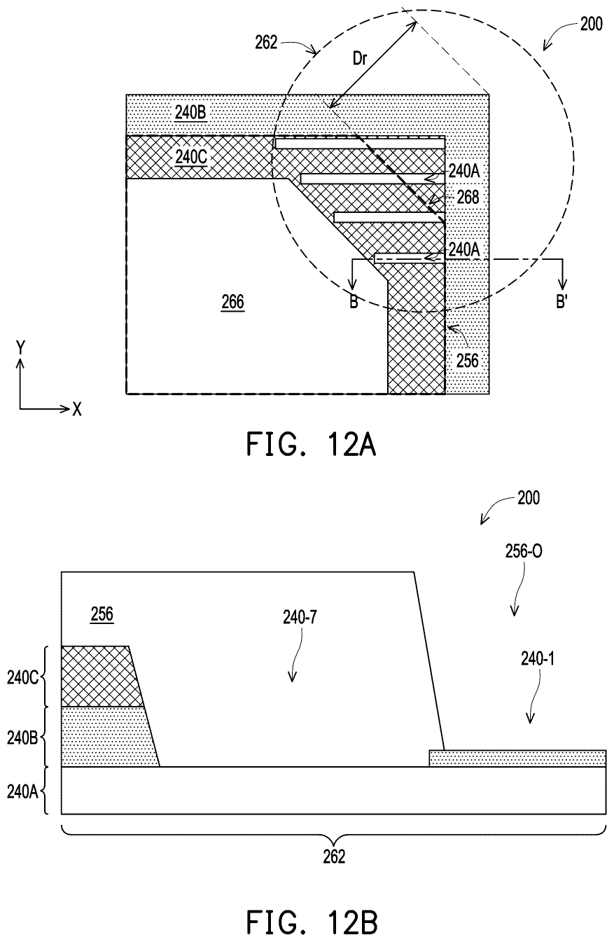

Referring to FIGS. 12A and 12B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 12A and 12B is similar to the IC structure 200 in FIGS. 8A and 8B. Similar descriptions are repeated for simplicity. Various openings 260 are formed in the polyimide layer 256 and the passivation structure 240, and are separately referred to as 256-O, 240-1 and 240-7.

In the present embodiment, the polyimide layer 256 is patterned to have an opening 256-O on the edge of the chip corner region 262 while the polyimide layer 256 fill the area enclosed in the dashed line box in FIG. 12A. The opening 256-O of the polyimide layer 256 is similar to the opening 256-O in FIGS. 6A and 6B.

In the present embodiment, the passivation structure 240 is patterned to have an opening 240-1, and a trench 240-7. The opening 240-1 of the passivation structure 240 is similar to the opening 240-1 of the passivation structure 240 in FIGS. 6A and 6B.

The trenches 240-7 are similar to the trenches 240-2, 240-3 in FIGS. 6A and 6B. However, the trenches 240-7 are configured differently. The trenches 240-7 include a plurality of trenches designed as straight lines and configured in parallel with each other. The number of, the widths of, the lengths of, and the spacing between the trenches 240-7 are optimized for maximized effect of the stress releasing. In the disclosed embodiments, the number of the trenches 240-7 is 4 but can be any proper number, such as 3 or 5. The lengths of the trenches 240-7 are different. Each of the trenches 240-7 is spanning between the edges (including the tilted edge 268) of the polyimide layer 256 and the edges (including a tilted edge) of the circuit region 266, resulting in the trenches 240-7 with one side ends aligned and with another side ends not aligned. In some embodiments, the trenches 240-7 are evenly configured with a same width W and a same spacing S. In furtherance of the embodiments, the width W and the spacing S are equal as W=S. In some embodiments, W or S is greater than 1 μm. In some embodiments, the trenches 240-7 have the lengths ranging between 5 μm and 20 μm.

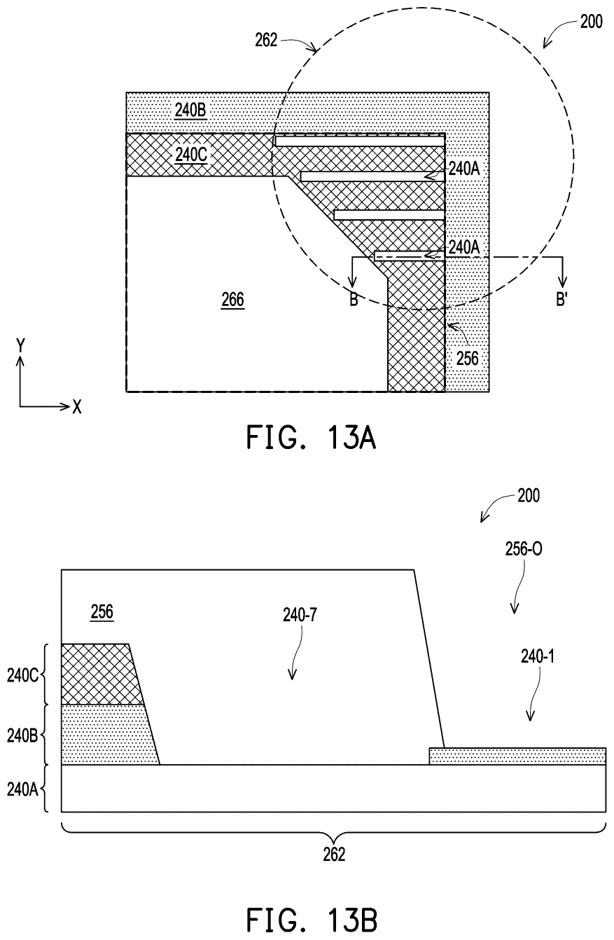

Referring to FIGS. 13A and 13B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 13A and 13B is similar to the IC structure 200 in FIGS. 12A and 12B. However, the tilted edge of the polyimide layer 256 is eliminated. Instead, the polyimide layer 256 has edges along X or Y direction, Similar descriptions are repeated for simplicity.

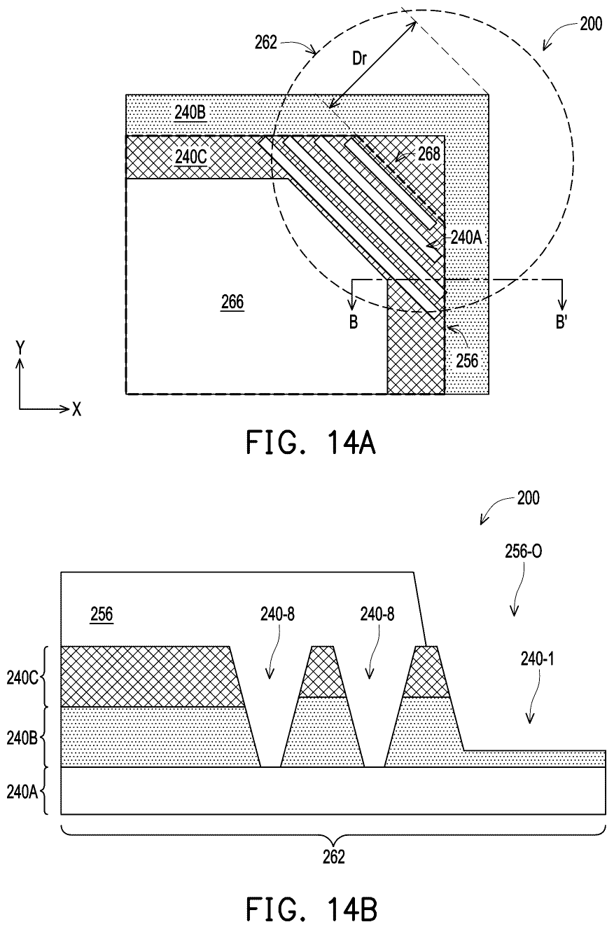

Referring to FIGS. 14A and 14B, the IC structure 200 only illustrates the passivation structure 240 and polyimide layer 256 in the chip corner region 262 and the openings (referred to by the numeral 260 in FIGS. 2A-2C) formed therein and designed for reducing and releasing the stress. The IC structure 200 in FIGS. 14A and 14B is similar to the IC structure 200 in FIGS. 12A and 12B. Similar descriptions are repeated for simplicity. Various openings 260 are formed in the polyimide layer 256 and the passivation structure 240, and are separately referred to as 256-O, 240-1 and 240-8.

In the present embodiment, the polyimide layer 256 is patterned to have an opening 256-O on the edge of the chip corner region 262 while the polyimide layer 256 fill the area enclosed in the dashed line box in FIG. 14A. The opening 256-O of the polyimide layer 256 is similar to the opening 256-O in FIGS. 12A and 12B.

In the present embodiment, the passivation structure 240 is patterned to have an opening 240-1, and a trench 240-8. The opening 240-1 of the passivation structure 240 is similar to the opening 240-1 of the passivation structure 240 in FIGS. 12A and 12B.

The trenches 240-8 are similar to the trenches 240-7 in FIGS. 12A and 12B. The trenches 240-8 include a plurality of trenches designed as straight lines and configured in parallel with each other However, the trenches 240-8 are configured differently, specifically being in parallel with the tilted edge 268 of the polyimide layer 256. The number of, the widths of, the lengths of, and the spacing between the trenches 240-8 are optimized for maximized effect of the stress releasing. In the disclosed embodiments, the number of the trenches 240-8 is 4 but can be any proper number, such as 3 or 5. The lengths of the trenches 240-8 are different. Each of the trenches 240-7 is spanning between the first edge (along X direction) and the second edge (along Y direction) of the polyimide layer 256, resulting in the trenches 240-8 with both ends not aligned. In some embodiments, the trenches 240-7 are evenly configured with a same width W and a same spacing S. In furtherance of the embodiments, the width W and the spacing S are equal as W=S. In some embodiments, W or S is greater than 1 μm. In some embodiments, the trenches 240-7 have the lengths ranging between 10 μm and 20 μm.

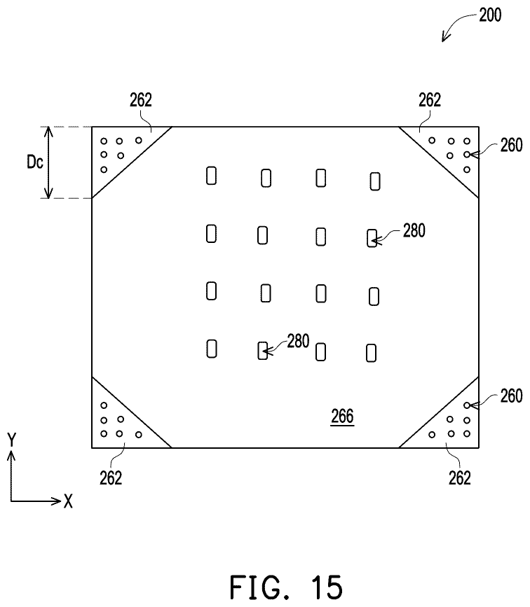

FIG. 15 is a top view of the IC structure 200, in portion, constructed according to some embodiments. Particularly, the polyimide layer 256 includes openings 256-O on the chip corner regions 262 but further includes openings 280 (as illustrated as 252 in FIG. 2A) in the circuit region 266 for conductive bumps 258 (as illustrated in FIG. 2B). The openings 280 of the polyimide layer 256 for the conductive bumps 258 in the circuit region 266 are also designed with proper shape and dimensions for stress releasing. In some embodiments, the openings 280 of the polyimide layer 256 in the circuit region 266 can have shape adjusted to reduce the stress and to effectively release the stress, such as round, square, rectangle, or rectangle with round corner. In some embodiment, the ratio of the length Lp over Wp is greater than 2, such as 3, or ranging between 2.2 and 4.

The polyimide layer 256 has a thickness Tp is also adjusted to reduce the stress or release the stress, such as thicker than the thickness Tu at of the underfill 119. In some embodiments, the ratio of Tp/Tu ranges between 4 and 5.

The present disclosure provides an IC structure and a method making the same in various embodiments. Especially, the IC structure includes a packaging structure with designed pattern to release stress and enhance packaging yield. The disclosed IC structure includes various structure features and fabrication steps to provide collective structure to reduce stress and delamination in the packaging, especially packaging structure in system-on-chip (SoC) flip-chip structures. In the present disclosure, an IC structure is configured to add trench or hole pattern into to the packaging materials, such as polyimide or silicon nitride of the passivation layer in chip corner areas to release corner stress, thereby enhancing SoC Flip chip (FC) package yield. Those trenches or holes are referred to as stress-release pattern. The stress-release pattern is arranged within the chip corner area (keep-out zone, KOZ). The stress-release pattern is defined on a photomask and is transferred to the packaging material through lithography process and etching. The disclosed IC structure and the method making the same can effectively reduce the stress, release the stress, and eliminate the delamination failure.

In one example aspect, the present disclosure provides an integrated circuit (IC) structure that includes a substrate having a circuit region and a chip corner region; IC devices formed on the substrate within the circuit region; a passivation layer formed over the IC devices; and a polyimide layer formed over the passivation layer, wherein the passivation layer and the polyimide layer include a stress-release pattern formed in the chip corner region.

In another example aspect, the present disclosure provides an integrated circuit (IC) structure that includes a substrate; a plurality of semiconductor chips attached to the substrate and electrically connected to the substrate; and a underfill material filled in spaces between the semiconductor chips and the substrate. The plurality of semiconductor chips includes a first semiconductor chip. The first semiconductor chip includes a semiconductor substrate having a circuit region and a chip corner region, IC devices formed on the semiconductor substrate within the circuit region, and a passivation layer formed over the IC devices, wherein the passivation layer includes a stress-release passivation pattern formed in the chip corner region.

In yet another example aspect, the present disclosure provides a method of making an integrated circuit (IC) structure. The method includes receiving a semiconductor substrate having a circuit region and chip corner region; forming IC devices on the semiconductor substrate within the circuit region and an interconnect structure over the IC devices; forming a passivation layer over the interconnect structure; patterning the passivation layer to form a stress-release passivation pattern within the chip corner region; forming a polyimide layer on the passivation layer; and patterning the polyimide layer to form a stress-release polyimide pattern within the chip corner region, wherein the stress release passivation pattern and the stress release polyimide pattern are different.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit (IC) structure, comprising:
a substrate having a circuit region and a chip corner region;
IC devices formed on the substrate within the circuit region;
a passivation layer formed over the IC devices; and
a polyimide layer formed over the passivation layer, wherein the passivation layer and the polyimide layer include a stress-release pattern formed in the chip corner region, wherein the stress-release pattern includes a plurality of trenches.

2. The IC structure of claim 1, wherein
the substrate includes a first edge along a first direction and a second edge along a second direction being perpendicular to the first direction;
the chip corner region is defined in a corner between the first and second edges; and
the polyimide layer includes an opening in the chip corner region, the opening has a tilted edge that is not in parallel with any of the first and second directions.

3. The IC structure of claim 2, wherein the trenches are formed in the passivation layer, and wherein the passivation layer includes a first silicon nitride layer, an un-doped silica glass (USG) layer over the first silicon nitride layer, and a second silicon nitride layer over the USG layer.

4. The IC structure of claim 3, wherein each of the trenches extends to the first silicon nitride layer.

5. The IC structure of claim 3, wherein each of the trenches includes a first segment being in parallel with the tilted edge.

6. The IC structure of claim 5, wherein the each of the trenches includes a second segment being in parallel with X direction, and a third segment being in parallel with Y direction, the first, second and third segments forming a continuous trench.

7. The IC structure of claim 3, wherein the trenches are straight trenches being in parallel with each other.

8. The IC structure of claim 7, wherein the trenches are in parallel with X direction.

9. The IC structure of claim 7, wherein the trenches are in parallel with the tilted edge.

10. The IC structure of claim 1, wherein the stress-release pattern includes a plurality of round holes formed in the passivation layer within the chip corner region.

11. An integrated circuit (IC) structure, comprising:
a substrate;
a plurality of semiconductor chips attached to the substrate and electrically connected to the substrate; and
an underfill material filled in spaces between the semiconductor chips and the substrate, wherein the plurality of semiconductor chips includes a first semiconductor chip, and wherein the first semiconductor chip further includes
a semiconductor substrate having a circuit region and a chip corner region,
IC devices formed on the semiconductor substrate within the circuit region, and
a passivation layer formed over the IC devices, wherein the passivation layer includes a stress-release passivation pattern formed in the chip corner region, and wherein the stress-release pattern includes a plurality of trenches.

12. The IC structure of claim 11, further comprising a lid configured over the semiconductor chips and secured to the substrate, wherein the semiconductor chips are enclosed by the lid and the substrate.

13. The IC structure of claim 11, wherein the substrate includes a first surface and a second surface opposite from the first surface, wherein the semiconductor chips are attached to the first surface of the substrate, and wherein the IC structure further includes large-scale-integrated passive devices (LS-IPDs) formed on the second surface of the substrate.

14. The IC structure of claim 11, wherein the first semiconductor chip further includes a polyimide layer formed over the passivation layer, and wherein the polyimide layer includes a stress-release polyimide pattern formed in the chip corner region.

15. The IC structure of claim 14, wherein
the first semiconductor chip includes a first edge along a first direction and a second edge along a second direction being perpendicular to the first direction;
the chip corner region is defined in a corner between the first and second edges; and
the stress-release polyimide pattern of the polyimide layer includes an opening in the chip corner region, the opening has a tilted edge that is not in parallel with any of the first and second directions.

16. The IC structure of claim 15, wherein the trenches of the stress-release passivation pattern are formed in the passivation layer, and wherein the passivation layer includes a first silicon nitride layer, an un-doped silica glass (USG) layer over the first silicon nitride layer, and a second silicon nitride layer over the USG layer.

17. The IC structure of claim 16, wherein each of the trenches includes
a first segment being in parallel with the tilted edge;
a second segment being in parallel with the first direction; and
a third segment being in parallel with the second direction, wherein the first, second and third segments form a continuous trench.

18. The IC structure of claim 16, wherein the trenches are straight trenches being in parallel with each other, and wherein the trenches are in parallel with the tilted edge.

19. A method of making an integrated circuit (IC) structure, comprising:
receiving a semiconductor substrate having a circuit region and chip corner region;
forming IC devices on the semiconductor substrate within the circuit region and an interconnect structure over the IC devices;
forming a passivation layer over the interconnect structure;
patterning the passivation layer to form a stress-release passivation pattern within the chip corner region;
forming a polyimide layer on the passivation layer; and
patterning the polyimide layer to form a stress-release polyimide pattern within the chip corner region, wherein the stress-release passivation pattern and the stress-release polyimide pattern include different openings.

20. The method of claim 19, wherein
the semiconductor substrate includes a first edge along a first direction and a second edge along a second direction being perpendicular to the first direction;
the chip corner region is defined in a corner between the first and second edges;
the patterning the polyimide layer includes patterning the polyimide layer to form the stress-release polyimide pattern having an opening with a tilted edge that are not in parallel with any of the first and second directions; and
the patterning the passivation layer includes patterning the passivation layer to form the stress-release passivation pattern having multiple trenches that are parallel with the tilted edge.
